(19) United States
(12) Patent Application Publication
(10) Pub. No.: US 2010/0101901 A1
(43) Pub. Date: Apr. 29, 2010

(54) ELECTRIC CONTROL BRAKING DEVICE

(75) Inventor: Sebastien Gay, Montigny le Bretonneux (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: RENAULT S.A.S, Boulogne Billancourt (FR)

(21) Appl. No.: 12/524,374

(22) PCT Filed: Feb. 7, 2008
(86) PCT No.: PCT/FR08/50188

§ 371 Date: Jul. 24, 2009

(30) Foreign Application Priority Data
Feb. 14, 2007 (FR) 0753246

(51) Int. Cl. B60L 7/00; H01L 41/06

(52) U.S. Cl. 188/161; 310/26

(57) ABSTRACT

The invention relates to a braking device that comprises an electric motor (1) capable of acting with the means (2) for the quick movement of the pads (3) into contact with a disk (4) or a drum, and a magnetostrictive actuator capable of generating a clamping force on the pads and against the disk or the drum. The magnetostrictive actuator comprises at least one winding (5) of a magnetic material on a holder (5a).

The invention relates to the technical sector of braking in general and more particularly relates to an electrically controlled braking device.

Usually, in a known manner, this type of braking uses at least one actuator, most often in the form of an electric motor, which must, on the one hand, allow a rapid movement, in order to bring, for example, two pads into contact with a brake disk or drum and, on the other hand, to exert a considerable force in order to clamp the pads against the surface of the disk or drum, in order to produce a braking torque. The use of a single actuator to perform these two functions of movement and clamping is not sufficient. That is why the known solutions often use an electric motor and a ball screw to perform the rapid movement function and a magnetostrictive actuator to perform the clamping force function.

With this solution, the electric motor can be designed for a weak power that is necessary and limited to the rapid movement of the pads before the latter are in contact with the disk or drum. The pads therefore put up very little resistance. An electric motor with conventional characteristics, rotating at high rotation speeds, while being compact, can therefore be used.

The function of the ball screw is to ensure the irreversibility of the device, considering that a force coming from the electric motor makes it possible to move the pads, while a force originating from these pads provides no movement from any side. The magnetostrictive actuator is situated on the side of the pads and is actuated when the motor has finished pressing the pads against the disk or the drum.

Once the pads are pressed against the disk or drum, the resistance encountered by the electric motor exceeds that accepted by the motor. The electric motor is switched off and the magnetostrictive actuator is supplied to perform the function of clamping the pads.

Note that, in a perfectly well known manner for those skilled in the art, it is advantageous to use magnetostriction in the braking field because, by definition, it makes it possible to exert a considerable force with limited movement. The magnetostrictive effect is obtained from certain magnetic materials such as nickel and cobalt, and their alloy with iron. However, better results are obtained with rare earths and their alloy with iron.

Advantageously, it is possible to cite Terfenol-D which is an alloy of iron, dysprosium and terbium.

In the known solutions and in the technical braking field, the magnetostrictive actuator consists of a simple bar of Terfenol-D magnetized longitudinally by an electromagnet.

A solution of this type emerges from the teaching of patent EP 0988467. With this solution, it is necessary to magnetize a significant length of the bar in order to obtain an elongation compatible with the deformation of the pads under the clamping force. This makes it necessary to use considerable magnetostrictive forces, which for example rules out iron and cobalt. On the other hand, the use of Terfenol-D, which has good characteristics, poses integration and cost problems.

The invention has the objective of remedying these disadvantages in a simple, sure, effective and rational manner.

The problem that the invention proposes to solve is that of producing an electrically controlled braking device which performs the functions mentioned above while being compact, having a low manufacturing cost and having high energy performance, low consumption and a broad bandwidth.

To solve such a problem, according to the invention, the magnetostrictive actuator consists of at least one winding of a magnetic material on a base.

Note that the electrically controlled braking device is of the type such as those comprising an electric motor capable of acting on a means in order to allow a rapid movement of the pads into contact with a disk or a drum and a magnetostrictive actuator capable of creating a clamping force on the pads against the disk or the drum.

According to this underlying feature of the invention, the material may be an alloy of iron and cobalt, therefore consisting of a winding of medium bulk at low cost, or else be made of Terfenol-D in order to obtain a winding of small bulk.

According to another feature, the magnetization of the winding material may be carried out by an electromagnet or by a permanent magnet.

To solve the problem posed of reducing the magnetic losses by short circuit, the winding is of rectangular section that is thin in the longitudinal direction and thick in the radial direction.

Various embodiments may be envisaged for producing the magnetostrictive actuator.

For example, the magnetostrictive actuator has a rotary or linear magnetic circuit, with a variable geometry, and actuated by any type of actuator, particularly by an electric motor.

Alternatively, in another embodiment, the magnetostrictive actuator is a fixed magnetic circuit with a permanent magnet surrounded by an electromagnet traversed by very intense and brief pulses of magnetizing current.

The invention is explained below in greater detail with the aid of the figures of the appended drawings in which:

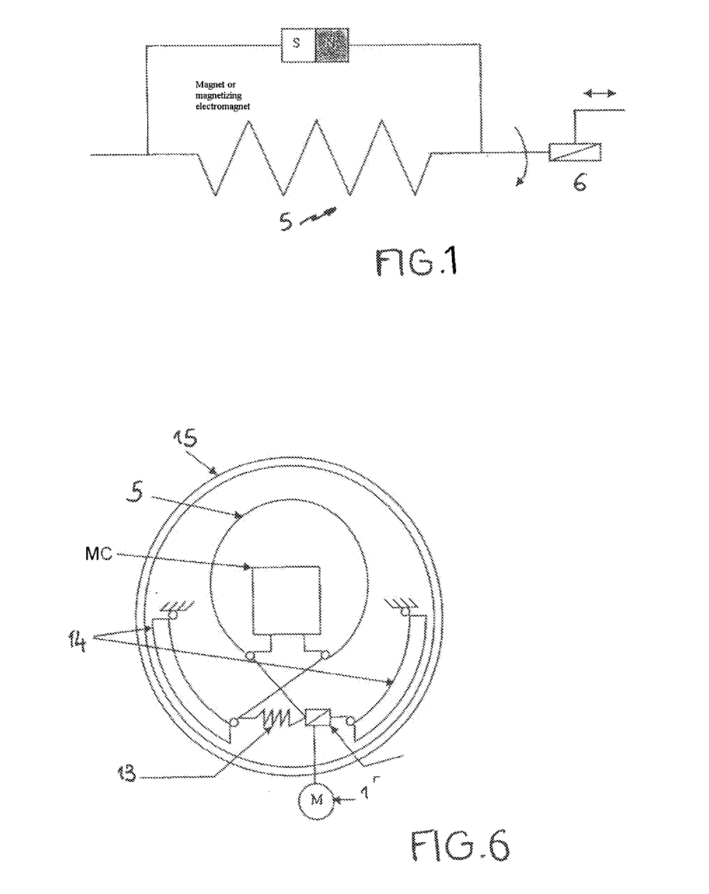

FIG. 1 shows the principle of the magnetostrictive actuator according to the invention;

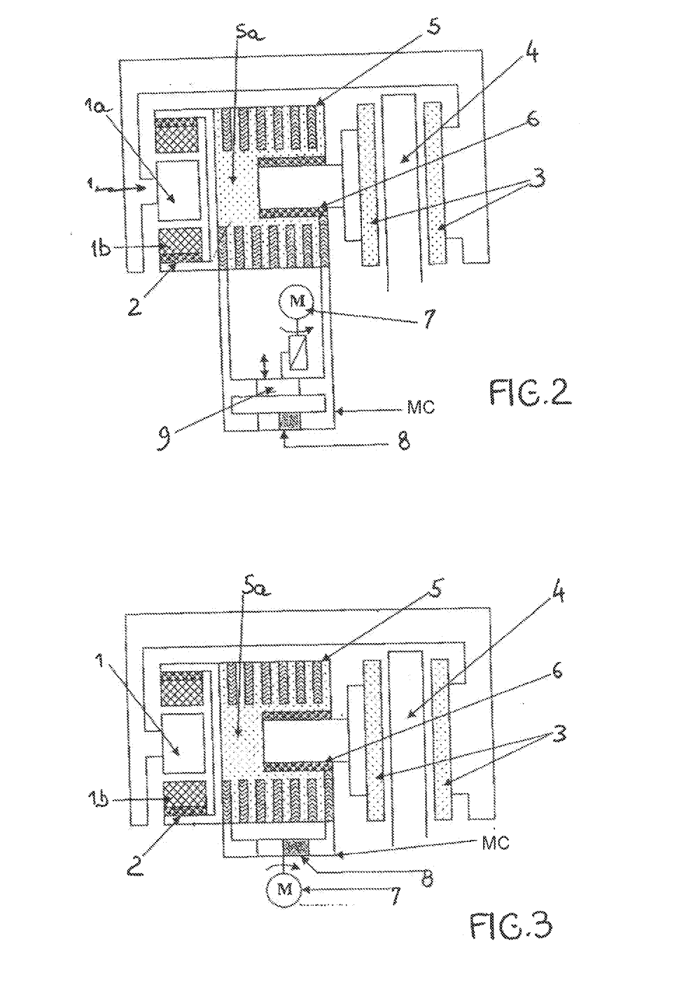

FIG. 2 is a view of a schematic nature showing an exemplary embodiment of the electric braking device, in the case of a magnetostrictive actuator with a magnetic circuit and with rotary variable geometry actuated by an electric motor;

FIG. 3 is a view similar to FIG. 2 in the case of a magnetostrictive actuator with a magnetic circuit with linear variable geometry actuated by an electric motor;

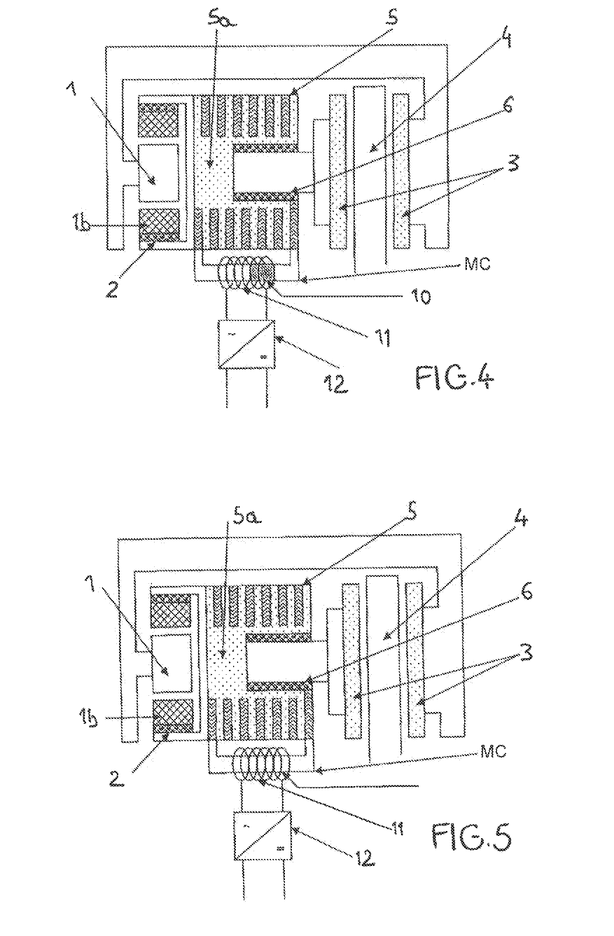

FIG. 4 is a view corresponding to FIG. 2 in which the magnetic circuit with variable geometry is replaced by a magnetic circuit that is fixed and has a permanent magnet surrounded by an electromagnet traversed by very intense and very brief pulses of magnetizing current;

FIG. 5 is a view similar to FIG. 4, the magnetostrictive material being magnetized by the electromagnet permanently supplied by a direct current;

FIG. 6 shows the application of the device to drum brakes.

In a known manner, as the figures of the drawings schematically show, the electrically controlled braking device comprises an electric motor (1) mounted in combination with, for example, a ball screw (2) in order to allow the rapid movement of brake pads (3) designed to interact with a disk (4) or other element. In combination with the motor (1), the device comprises a magnetostrictive actuator (5) capable of creating a clamping force on the pads (3) against the disk (4) or drum. In the figures of the drawings, (1a) represents the stator of the motor or other movement actuator, while reference number (1b) shows the rotor of the actuator (1), which rotor is mounted in combination with the ball screw (2).

According to one feature at the base of the invention, the magnetostrictive actuator consists of a winding (5) mounted on a core (5a) serving as a guide. The guide (5a) is also mounted in combination with, for example, a ball screw (6) or other element. As shown in the figures of the drawings, the winding (5) has, between each turn, an air gap so as to limit the magnetic losses by short circuit. Therefore, a winding with rectangular section that is thin in the longitudinal direction and thick in the radial direction is particularly well suited.

As indicated, the winding (5) may be made of a mixture of iron and cobalt. As an indication, such a winding may be contained in a length of approximately 5 cm. The winding (5) may equally be made of Terfenol-D making it possible to obtain a channel of the order of 2 mm.

More generally, the winding (5) is made of an alloy deforming under the effect of a magnetic field.

The magnetostrictive winding (5) may be magnetized either by an electromagnet or by a permanent magnet. In this respect, it should be observed that the electromagnet produces a magnetic field that is easy to control and consequently so is the force that the magnetostrictive winding exerts. On the other hand, the electromagnet consumes much energy.

The permanent magnet has a zero energy consumption and is extremely compact as a result of the absence of electric power supply and of the material itself. Controlling the magnetic field is more awkward and may be carried out by means of a variable-geometry magnetic circuit, as indicated in the rest of the description.

In the case of a magnetostrictive actuator, the magnetic material of which is magnetized by a permanent magnet, it seemed advantageous to use a variable-geometry magnetic circuit.

Various solutions may be envisaged.

In FIG. 2, the magnetic circuit (MC) has a rotary variable geometry and is actuated by an electric motor (7). The permanent magnet is indicated by (8). Clearly, this electric motor (7), which actuates a movable shunt (9), can be replaced by any other type of actuator such as an electromagnetic plunger, an electroactive polymer, a thermal dilation actuator, a physioelectric actuator, etc.

In FIG. 3, the magnetic circuit (MC) has a linear variable geometry and is actuated either by an electric motor (7) or, as indicated above, by any other type of actuator.

In one embodiment, the variable-geometry magnetic circuit (MC) is replaced by a fixed magnetic circuit and a permanent magnet (10) surrounded by an electromagnet (11) traversed by brief and intense pulses of current. The magnetizing electromagnet (11) is slaved to an electronic control element (12). It should be noted that the pulses magnetize the magnet by imposing on it the desired magnetic field value. In this embodiment, it is preferable to use conventional magnets such as ferrites or alnicos. It should be noted that, in this embodiment, the electromagnet (11) could be wound directly onto the magnetic circuit.

In the case of a drum brake, the magnetostrictive winding (5) rests on a guide. The winding uses either a material that expands under the effect of a field, in the case of a brake actuated by the establishment of the field, or a material that contracts under the effect of the field (a brake actuated by the interruption of the field). Cables or rods are used to transmit the forces between the magnetostrictive winding (5) and the magnetic circuit (MC). A pretensioner spring (13) operates in compression, that is to say by pushing the pads (14) onto the drum (15). This spring is slaved to the magnetostrictive winding.

In this application to a drum brake, the magnetic circuit (MC) can be made according to the various embodiments described and illustrated in the case of a disk brake.

The device according to the invention may be applied in all cases requiring braking or clamping of a part after compensation of a relatively large clearance.

Amongst these various applications, it is possible to cite:
Braking of all types of vehicles: automobile, motorcycle, trucks, buses, trains, aircraft with a preference for the applications needing compactness, lightness and/or a great bandwidth.
Braking of elevators with a brake that is applied by default.
Clutch-operated chair lifts and cable cars.
Brakes and clutches for automatic gearboxes.
Industrial robot pincers: the movement actuator makes it possible to grasp parts of different sizes and allows a margin of maneuver in order to allow the pincer to move away from the part once the latter has been released. The magnetostrictive actuator provides a powerful clamping in order to hold heavy parts and/or slippery parts (smooth surface, coated in grease).

The advantages emerge clearly from the description; particular emphasis is placed on the following as a reminder:
On the matter of compactness, the magnetostrictive winding allows a greater compactness particularly lengthwise. At equal space requirement, a magnetostrictive winding makes it possible to use a greater length of material and consequently to obtain a longer travel of the actuator when clamping.
On the matter of costs resulting from the possibility of using iron cobalt alloys.
On the matter of energy performance and low power consumption resulting from the small size and powerful actuators, energy consumption limited to the transitional phases, and from the possibility of recovering the energy consumed in the magnetization of the circuit, in the case of variable-geometry magnetic circuits.
Note also that the low energy consumption of the device makes it possible to envisage it being supplied at reduced voltage of 14 V DC, greatly limiting fuel consumption.
On the matter of broad bandwidth, which extends beyond 20 kHz, making it possible to design a hybrid actuator by observing that the bandwidth of a magnetostrictive actuator depends essentially on the bandwidth of the device which applies the magnetizing field. The bandwidth may further be increased with magnets magnetized by current pulses. The use of a very large bandwidth makes it possible to supply services of the ESP (Electronic Stability Program) type with low-amplitude forces applied.
On the matter of cost reductions associated with the electronics resulting from the possibility of using low-power electric motors. The low energy consumption and low energy dissipation of the electronics make it possible to reduce the stresses in cooling so that, from a thermal point of view, it is possible to place the electronics on the caliper as such, thereby contributing to the cost reduction.
On the matter of the order of magnitude of the clamping forces generated by magnetostriction.

1. An electrically controlled braking device comprising an electric motor (1) capable of acting on a means (2) in order to allow a rapid movement of pads (3) into contact with a disk (4) or a drum and a magnetostrictive actuator capable of creating a clamping force on the pads against the disk or the drum, characterized in that the magnetostrictive actuator consists of at least one winding (5) of a magnetic material on a base (5a).

2. The device as claimed in claim 1, characterized in that the material is an alloy deforming under the effect of a magnetic field.

3. The device as claimed in claim 2, characterized in that the magnetic material (5) is an alloy of iron and cobalt.

4. The device as claimed in claim 2, characterized in that the magnetic material (5) is made of Terfenol-D.

5. The device as claimed in claim 1, characterized in that the magnetic material is magnetized by an electromagnet.

6. The device as claimed in claim 1, characterized in that the magnetic material is magnetized by a permanent magnet.

7. The device as claimed in claim 1, characterized in that the winding (5) is of rectangular section that is thin in the longitudinal direction and thick in the radial direction.

8. The device as claimed in claim 6, characterized in that the permanent magnet is mounted in combination with a means capable of controlling its magnetic field.

9. The device as claimed in claim 1, characterized in that the magnetostrictive actuator (5) has a variable-geometry rotary magnetic circuit, actuated mainly by an electric motor.

10. The device as claimed in claim 1, characterized in that the magnetostrictive actuator (5) is a variable-geometry linear magnetic circuit, actuated mainly by an electric motor.

11. The device as claimed in claim 1, characterized in that the magnetostrictive actuator (5) has a fixed magnetic circuit and a permanent magnet (10) surrounded by an electromagnet (12) traversed by very intense and brief pulses of current.

12. The device as claimed in claim 1, characterized in that the magnetostrictive material is magnetized by an electromagnet permanently supplied by a direct current.
